(19) United States
(12) Patent Application Publication
(10) Pub. No.: US 2007/0056627 A1
(43) Pub. Date: Mar. 15, 2007

(54) Sensitized semiconductor solar cell

(75) Inventors: Tsun-Neng Yang, Taoyuan (TW); Shan-Ming Lan, Taoyuan (TW); Chin-Chen Chiang, Taoyuan (TW)

Correspondence Address: TROXELL LAW OFFICE PLLC;SUITE 1404, 5205 LEESBURG PIKE, FALLS CHURCH, VA, 22041, US

(73) Assignee: Atomic Energy Council - Institute of Nuclear Energy Research

(21) Appl. No.: 11/221,852

(22) Filed: Sep. 9, 2005

(51) Int. Cl. H01L 31/00

(52) U.S. Cl. 136/263

(57) ABSTRACT

The present invention provides a solar cell that absorbs a light source within a spectrum range from ultraviolet to far infrared with two surfaces by an absorption layer made of a semiconductor.

### FIELD OF THE INVENTION

The present invention relates to a solar cell; more particularly, relates to absorbing a light source within a spectrum range from ultraviolet to far infrared.

### DESCRIPTION OF THE RELATED ART

A solar cell of a prior art disclosed in Taiwan comprises a donor/acceptor complex deposed between a first electrode and a second electrode, where at least a part of the first electrode and a part of the second electrode are previous to light. The donor/acceptor complex comprises a light-absorption polymer as an electron donor after absorbing light, and carbon pellets as an electron acceptor, where the light-absorption polymer comprises an average thickness between 5 nm and 10 nm. Consequently, a solar cell for absorbing light source is constructed.

The solar cell of the prior art is a solar cell for absorbing light source; yet, the donor/acceptor complex of the light-absorption polymer can absorb light source only with one surface. Thus, the absorption rate of the light-absorption polymer is not good enough. Besides, the solar cell of the prior art cannot absorb a light source within a spectrum range from ultraviolet to far infrared. So, the prior art does not fulfill all users' requests on actual use.

### SUMMARY OF THE INVENTION

Therefore, the main purpose of the present invention is to absorb a light source within a spectrum range from ultraviolet to far infrared by an absorption layer made of a semiconductor.

To achieve the above purpose, the present invention is a sensitized semiconductor solar cell comprising a first substrate; a transparent conductive layer deposed on a surface of the first substrate; a first anti-reflection layer deposed on another surface of the first substrate; an absorption layer deposed on a surface of the transparent conductive layer; an electrolyte layer deposed on a surface of the absorption layer; a metal electrode deposed on a surface of the electrolyte layer; a second substrate deposed on a surface of the metal electrode; and a second anti-reflection layer deposed on a surface of the second substrate. Accordingly, a novel sensitized semiconductor solar cell is obtained.

### BRIEF DESCRIPTIONS Of THE DRAWINGS

The present invention will be better understood from the following detailed description of the preferred embodiment according to the present invention, taken in conjunction with the accompanying drawings, in which

FIG. 1 is an explosive view showing a cross-sectional surface of a preferred embodiment according to the present invention;

FIG. 2 is an assembly view showing the cross-sectional surface of the preferred embodiment according to the present invention; and

FIG. 3 is a view showing a state of use of the preferred embodiment according to the present invention.

### DESCRIPTION OF THE PREFERRED EMBODIMENT

The following description of the preferred embodiment is provided to understand the features and the structures of the present invention.

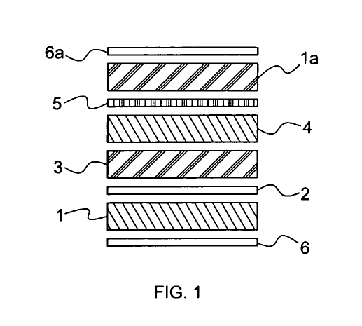

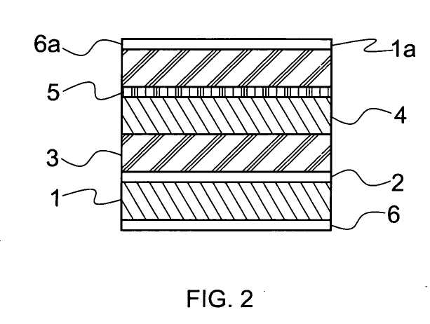

Please refer to FIG. 1 and FIG. 2, which are an explosive view and an assembly view showing a cross-sectional surface of a preferred embodiment according to the present invention. As shown in the figures, the present invention is a sensitized semiconductor solar cell, comprising a first and a second substrates 1, 1a, a transparent conductive layer 2, an absorption layer 3, an electrolyte layer 4, a metal electrode 5 and a first and a second anti-reflection layers 6, 6a, where the solar cell comprises two surfaces for absorbing a light source within a spectrum range from ultraviolet to far infrared.

The first substrate 1 is made of glass or PET (Polyethylene Terephthalate).

The transparent conductive layer 2 is deposed on the first substrate 1 and is made of conductive glass.

The absorption layer 3 is deposed on the transparent conductive layer 2 and is made of a light-absorption material of TiO₂—ₓNₓ:In. And, the absorption layer 3 comprises a wavelength range for absorption during 300 nm (nanometer) to 1,500 nm.

The electrolyte layer 4 is deposed on the absorption layer 3.

The metal electrode 5 is deposed on the electrolyte layer 4 and is made of TiN, Pt or Al. The metal electrode 5 comprises a film structure or a meshed structure for light-previousness and light-focusing.

The second substrate 1 a is deposed on the metal electrode 5 and is made of glass or PET.

The first and the second anti-reflection layers 6, 6a are deposed on the outside surface of the first and the second substrates and are each a si I icon quantum-dot film of SiNₓ for anti-reflection and light-concentrating. Hence, a novel sensitized semiconductor solar cell is obtained.

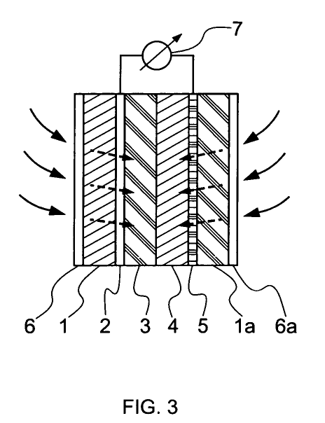

Please refer to FIG. 3, which is a view showing a state of use of the preferred embodiment according to the present invention. As shown in the figure, when using the present invention, the transparent conductive layer 2 and the metal electrode 5 are connected to a device outside 7. Sun light is absorbed by the absorption layer 3 from two surfaces of the solar cell to store energy. Because the absorption layer 3 comprises a wavelength range for absorption during 300 nm to 1,500 nm, a spectrum range of sunlight from ultraviolet to far infrared can be absorbed to extend the absorption of light source for providing energy for the device outside 7.

In addition, when manufacturing the present invention, a device for AP-CVD (Atmospheric Pressure Chemical Vapor Deposition) or PE-CVD (Plasma-Enhanced Chemical Vapor Deposition) can be used with a reaction raw material of TiC1₄+NH₃+TMI+H₂O (in vapor form) operating under a reaction temperature of 400˜600° C. or 300˜500° C. to obtain the absorption layer 3 with a thickness of a few μm.

To sum up, the present invention is a sensitized semiconductor solar cell, which absorbs a light source within a spectrum range from ultraviolet to far infrared with two surfaces.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A sensitized semiconductor solar cell, comprising;
(a) a first substrate;
(b) a transparent conductive layer deposed on a surface of said first substrate;
(c) a first anti-reflection layer deposed on another surface of said first substrate;
(d) an absorption layer deposed on a surface of said transparent conductive layer;
(e) an electrolyte layer deposed on a surface of said absorption layer;
(f) a metal electrode deposed on a surface of said electrolyte layer;
(g) a second substrate deposed on a surface of said metal electrode; and
(h) a second anti-reflection layer deposed on a surface of said second substrate.

2. The solar cell according to claim 1, wherein said first substrate is made of glass.

3. The solar cell according to claim 1, wherein said first substrate is made of PET (Polyethylene Terephthalate).

4. The solar cell according to claim 1, wherein said transparent conductive layer is made of conductive glass.

5. The solar cell according to claim 1, wherein said absorption layer is made of a light-absorption material of TiO₂—ₓNₓ:In.

6. The solar cell according to claim 1, wherein said absorption layer comprises a wavelength range of absorption during 300 nm (nanometer) to 1,500 nm.

7. The solar cell according to claim 1, wherein said metal electrode is made of TiN.

8. The solar cell according to claim 1, wherein said second substrate is made of glass.

9. The solar cell according to claim 1, wherein said second substrate is made of PET.

10. The solar cell according to claim 1 wherein said first anti-reflection layer and said second anti-reflection layer are each a silicon quantum-dot film of SiNₓ having anti-reflection and light-concentrating.
